(19) United States
(12) Patent Application Publication
(10) Pub. No.: US 2012/0132281 A1
(43) Pub. Date: May 31, 2012

(54) THIN-FILM SOLAR CELL AND MANUFACTURING METHOD THEREOF

(75) Inventors: CHIEN-PANG YANG, TAICHUNG COUNTY (TW); CHIH-HUNG YEH, TAICHUNG COUNTY (TW)

(73) Assignee: NEXPOWER TECHNOLOGY CORPORATION, TAICHUNG COUNTY (TW)

(21) Appl. No.: 12/954,795

(22) Filed: Nov. 26, 2010

(51) Int. Cl. H01L 31/0264; H01L 31/18; H01L 31/0272

(52) U.S. Cl. 136/260; 136/262; 136/264; 438/95; 257/E31.015

(57) ABSTRACT

A thin-film solar cell and a manufacturing method thereof are disclosed. The method of manufacturing the thin-film solar cell includes the steps of providing a substrate; forming a diffusion barrier layer on the substrate; forming a back electrode layer on the diffusion barrier layer; forming a precursor layer on the back electrode layer, and the precursor layer including at least Cu, In and Ga; providing an alkali layer on an upper surface of the precursor layer, and the alkali layer being formed of Li, Na, K, Rb, Cs, or an alkali metal compound; providing a selenization process for the precursor layer and the alkali layer to form an absorber layer, such that an atomic percentage concentration of the alkali metal in the absorber layer is ranged between 0.01%˜10%; forming at least a buffer layer on the absorber layer; and forming at least a front electrode layer on the buffer layer.

### FIELD OF THE INVENTION

The present invention relates to a thin-film solar cell and manufacturing method thereof, and more particularly to a thin-film solar cell and manufacturing method thereof, in which an absorber layer with a chalcopyrite Cu(In, Ga)Se₂ structure is formed and an absorber layer with a Cu(In, Ga)S₂ or Cu(In, Ga)(Se,S)₂ structure is further formed on a surface of the chalcopyrite Cu(In, Ga)Se₂ structure.

### BACKGROUND OF THE INVENTION

A solar cell is mainly a p-n junction semiconductor structure, which directly converts absorbed light energy into electric energy via a process known as photovoltaic effect. In recent years, to satisfy the demands for reducing material use, the development of thin-film solar cell has become a main trend in the solar cell field. While the thin-film solar cell can be advantageously produced at relatively low manufacturing cost, it needs improvement in terms of the efficiency, stability and production yield thereof.

Most of the currently available thin-film solar cells have an absorber layer mainly formed of amorphous silicon, microcrystalline silicon, CdTe, CuInSe₂ (CIS), Cu(In, Ga)Se₂ (CIGS) or the like. This is because these materials are direct bandgap semiconductor materials, and particularly, have bandgap values covering most part of the solar spectrum to thereby have very high light absorption coefficients. Some of these materials can also have a p-n junction through modification of their compositions.

A CuInSe₂ thin-film solar cell is formed from a plurality of overlaid individual thin-film layers, including from bottom to top a substrate, a back electrode layer, an absorber layer, a buffer layer, a window layer and a front electrode layer. The absorber layer has a chalcopyrite structure and belongs to a Group IB-IIIA-VIA compound. This type of absorber layer has excellent anti-interference ability and radiation-resistant ability, and accordingly, has long life time. A Cu(In, Ga)Se₂ thin-film solar cell is developed on the basis of the CuInSe₂ thin-film solar cell by substituting Ga for part of In. The Cu(In, Ga)Se₂ thin-film solar cell has a light absorption coefficient ranged between 1.02 eV and 1.68 eV, depending on different Indium and Gallium contents. Therefore, the Cu(In, Ga)Se₂ thin-film solar cell has conversion efficiency better than that of the CuInSe₂ thin-film solar cell.

Currently, the absorber layer of the CuInSe₂ thin-film solar cell or the Cu(In, Ga)Se₂ thin-film solar cell can be formed mainly in four ways, namely, sputtering-selenization, coevaporation, printing-selenization, and electroplating-selenization. In prior art, a precursor layer is formed by sputtering Cu, In and Ga, and then the absorber layer is formed via selenization. Alternatively, the absorber layer is directly formed via coevaporation of Cu, In, Ga, and Se.

However, since indium and gallium used in the CuInSe₂ thin-film solar cell and the Cu(In, Ga)Se₂ thin-film solar cell are precious metals that require very high cost and potentially prevent the two types of thin-film solar cells from being mass-produced. Moreover, the bandgap discontinuity between the absorber layer and the buffer layer as existed in the CuInSe₂ thin-film solar cell and the Cu(In, Ga)Se₂ thin-film solar cell requires improvement.

### SUMMARY OF THE INVENTION

To overcome the drawbacks in the prior art, a primary object of the present invention is to provide a thin-film solar cell and a manufacturing method thereof. The method of manufacturing the thin-film solar cell according to a first embodiment of the present invention includes the steps of providing a substrate; forming a back electrode layer on the diffusion barrier layer; forming a precursor layer on the back electrode layer, and the precursor layer including at least Cu, In and Ga; providing an alkali layer on an upper surface of the precursor layer; providing a selenization process for the precursor layer and the alkali layer to together form an absorber layer having a chalcopyrite Cu(In, Ga)Se₂ structure, such that an atomic percentage concentration of the alkali metal in the absorber layer is ranged between 0.01%˜10%; forming at least a buffer layer on the absorber layer; and forming at least a front electrode layer on the buffer layer. The first embodiment further comprises a step of forming a diffusion barrier layer on the substrate before the back electrode layer is formed. The atomic percentage concentration of the alkali metal in the absorber layer closer to the back electrode layer is smaller than the atomic percentage concentration of the alkali metal in the absorber layer closer to the buffer layer.

Therefore, with the selenization process provided in the thin-film solar cell and the manufacturing method thereof according to the first embodiment of the present invention, it is able to effectively control a content of the alkali metal in the absorber layer, help the crystal growth in the absorber layer to form crystals with relatively large grains, reduce grain boundaries, decrease resisitivity, increase carrier density and minimize defect density in the crystals.

Further, providing alkali metal sulfide as alkali layer forms Cu(In, Ga)S₂ or Cu(In, Ga)(Se,S)₂ on the surface of the absorber layer, it is able to enable an increased bandgap of the absorber layer, increased open circuit voltage, reduced bandgap discontinuity between the buffer layer and the absorber layer, and an upgraded conversion efficiency.

Additionally, the present invention provides a thin-film solar cell. The thin-film solar cell comprises a substrate, a back electrode layer, an absorber layer having a Cu (In, Ga)Se₂ structure, at least a buffer layer and at least a front electrode layer. The back electrode layer is formed on the substrate and the absorber layer is formed on the back electrode layer. The absorber layer is formed by a precursor layer and an alkali layer via a selenization process, and the back electrode layer includes at least Cu, In and Ga. The buffer layer is formed between the absorber layer and the front electrode layer. Further, an atomic percentage concentration of an alkali metal in the absorber layer is ranged between 0.01% and 10%. The atomic percentage concentration of the alkali metal in the absorber layer closer to the back electrode layer is lower than the atomic percentage concentration of the alkali metal in the absorber layer closer to the buffer layer.

The method of manufacturing the thin-film solar cell according to a second embodiment of the present invention includes the steps of providing a substrate; forming a back electrode layer on the diffusion barrier layer; providing a coevaporation process, so that an absorber layer having a chalcopyrite Cu(In, Ga)Se₂ structure is formed on the back electrode layer; providing an alkali metal sulfide for depositing on the absorber layer; providing a thermal annealing process, so that a Cu(In, Ga)S₂ or Cu(In, Ga)(Se,S)₂ structure is formed on the surface of the absorber layer; forming at least a buffer layer on the absorber layer; and forming at least a front electrode layer on the buffer layer. The second embodiment further comprises a step of forming a diffusion barrier layer on the substrate before the back electrode layer is formed.

Therefore, with the coevaporation process and the thermal annealing process provided in the thin-film solar cell and the manufacturing method thereof according to the second embodiment of the present invention, it is able to effectively control a content of the alkali metal in the absorber layer, help the crystal growth in the absorber layer to form crystals with relatively large grains, reduce grain boundaries, and minimize defects in the crystals.

Further, with the formation of the Cu(In, Ga)S₂ or Cu(In, Ga)(Se,S)₂ structure on the surface of the absorber layer, it is able to enable an increased bandgap of the absorber layer, increased open circuit voltage, reduced problem of bandgap discontinuity between the buffer layer and the absorber layer, and an upgraded conversion efficiency.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a flowchart showing the steps included in a method of manufacturing thin-film solar cell according to a first preferred embodiment of the present invention;

FIG. 2A is a conceptual view illustrating the process of manufacturing the thin-film solar cell according to the first preferred embodiment of the present invention;

FIG. 2B is a further conceptual view illustrating the process of manufacturing the thin-film solar cell according to the first preferred embodiment of the present invention;

FIG. 3 is a flowchart showing the steps included in a method of manufacturing thin-film solar cell according to a second preferred embodiment of the present invention; and

FIG. 4 is a conceptual view illustrating the process of manufacturing the thin-film solar cell according to the second preferred embodiment of the present invention.

### DETAILED DESCRIPTION OF THE PREFERRED EMBODIMENTS

The present invention discloses a thin-film solar cell and a manufacturing method thereof. Since the principle of photovoltaic conversion based on which the solar cell of the present invention works is known by one of ordinary skill in the art, it is not described in details herein. Meanwhile, it is understood the accompanying drawings are illustrated only for assisting in describing the present invention and is not necessarily in compliance with the exact or precise size proportion and part arrangement of a real product manufactured through implementing the present invention.

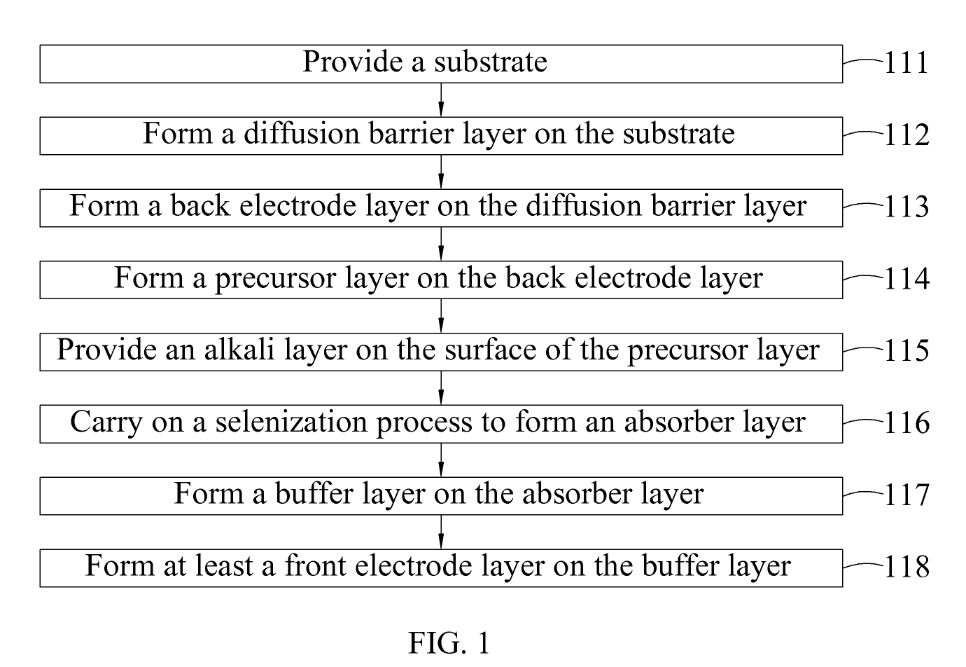

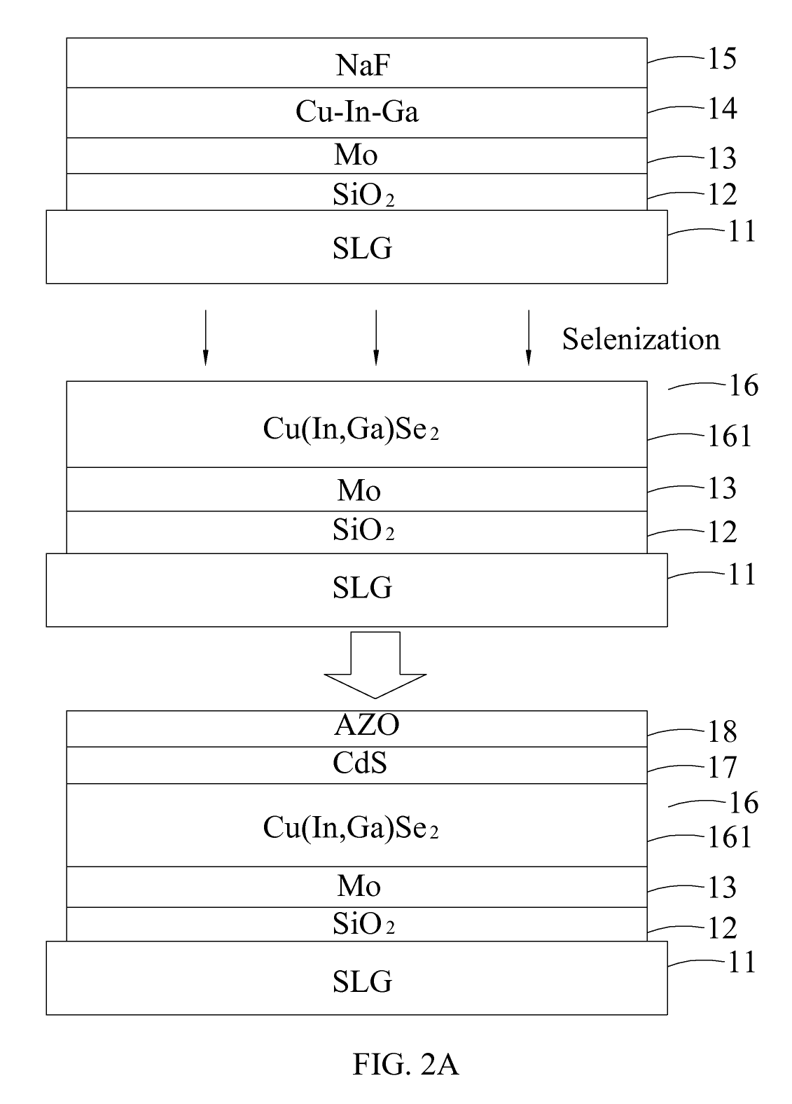

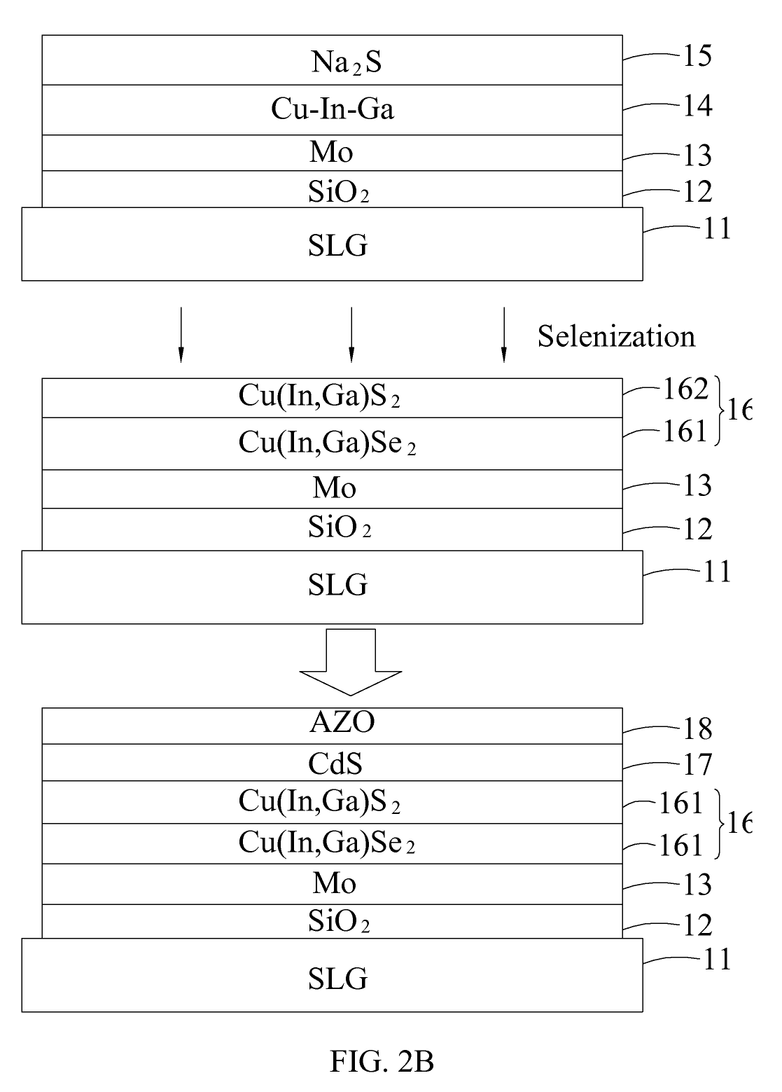

To achieve the aforesaid objects, a first preferred embodiment of the present invention is a method of manufacturing a thin-film solar cell. Please refer to FIGS. 1 and 2A. The method of manufacturing a thin-film solar cell according to the first preferred embodiment of the present invention includes the following steps:

Step 111: Providing a substrate 11. In the illustrated first preferred embodiment, the substrate is a soda-lime glass (SLG) substrate.

Step 112: Forming a diffusion barrier layer 12 on the substrate 11. In the illustrated first preferred embodiment, the diffusion barrier layer 12 is formed of SiO₂. The diffusion barrier layer 12 is an optional layer in the thin film solar cell. Thus, the step 112 can be omitted if the thin film solar cell does not have such structure.

Step 113: Forming a back electrode layer 13 on the diffusion barrier layer 12. A material for forming the back electrode layer 13 can be Mo, Ag, Al, Cr, Ti, Ni or Au; or can be FTO, ITO, ZnO, AZO, GZO, BZO or IZO.

Step 114: Forming a precursor layer 14 on the back electrode layer 13. The precursor layer 14 includes at least Cu, In, and Ga; and can also further include Se, O, Ag or Al. In the illustrated first preferred embodiment, the precursor layer 14 includes Cu, In and Ga.

Step 115: Forming an alkali layer 15 on the precursor layer 14. The alkali layer 15 can include an alkali metal element, such as Na, K, Li, Rb or Cs, or any chemical compound thereof; or can include a sulfide, such as Na₂S, Li₂S, K₂S, Rb₂S or Cs₂S. In the illustrated first preferred embodiment, the alkali layer 15 includes NaF, which is one of the alkali metals halides. By providing an alkali layer of an adequate amount of Na, it would be helpful in a subsequent crystal growth to form an absorber layer 16. A conventional way in the prior art for controlling the content of Na is to use a soda lime glass containing Na with a diffusion barrier layer, so as to deposit a layer of Na compound on the back electrode layer and then deposit an absorber layer or a precursor thereof on the Na compound layer. In this manner, an absorber layer with relatively large crystalline grains can be formed. However, in the present invention, the alkali layer 15 of Na compound is formed on the precursor layer 14 for properly controlling the content of Na thereof, in order to help the crystal growth in the absorber layer to form crystals with relatively large grains, reduce grain boundaries, decrease resisitivity, increase carrier density and minimize defect density in the crystals.

Step 116: Providing a selenization process. By providing a Se source on the alkali layer 15 of Na, the Se source can diffuse from an upper surface of the precursor layer 14 into the precursor layer 14 to carry out selenization. After the selenization, the precursor layer 14 and the alkali layer 15 are converted into an absorber layer 16 having a chalcopyrite Cu(In, Ga)Se₂ structure 161. The Se source used in the selenization process can be H₂Se, Se, Se vapor, or diethylselenide. Please refer to FIG. 2B. In the case the alkali layer 15 used is a sulfide, such as Na₂S (it is also possible to use Li₂S, K₂S, Rb₂S or Cs₂S as the alkali layer 15), the precursor layer 14 and the alkali layer 15 after the selenization would convert into an absorber layer 16 having a Cu(In, Ga)S₂ or Cu(In, Ga)(Se,S)₂ structure 162 formed on a surface of the chalcopyrite Cu(In, Ga)Se₂ structure 161. Further, in the thin-film solar cell manufactured either according to FIG. 2A or FIG. 2B, an atomic percentage concentration of the alkali metal (Na) in the absorber layer 16 is ranged between 0.01%˜10%. Additionally, the atomic percentage concentration of the alkali metal in the absorber layer closer to the back electrode layer is lower than the atomic percentage concentration of the alkali metal in the absorber layer closer to the buffer layer.

Step 117: Forming at least a buffer layer 17 on the absorber layer 16. The buffer layer 17 can be formed of CdS, ZnS, In₂S₃, CdSe, ZnSe, In₂Se₃, TiO₂, SnO₂, ZnO, or ZnMgO. In the illustrated first preferred embodiment, the buffer layer is formed of CdS.

Step 118: Forming at least a front electrode layer 18 on the buffer layer 17. The front electrode layer 18 can be formed of FTO, ITO, ZnO, AZO, GZO, BZO, or IZO. In the illustrated first preferred embodiment, the front electrode layer is formed of AZO.

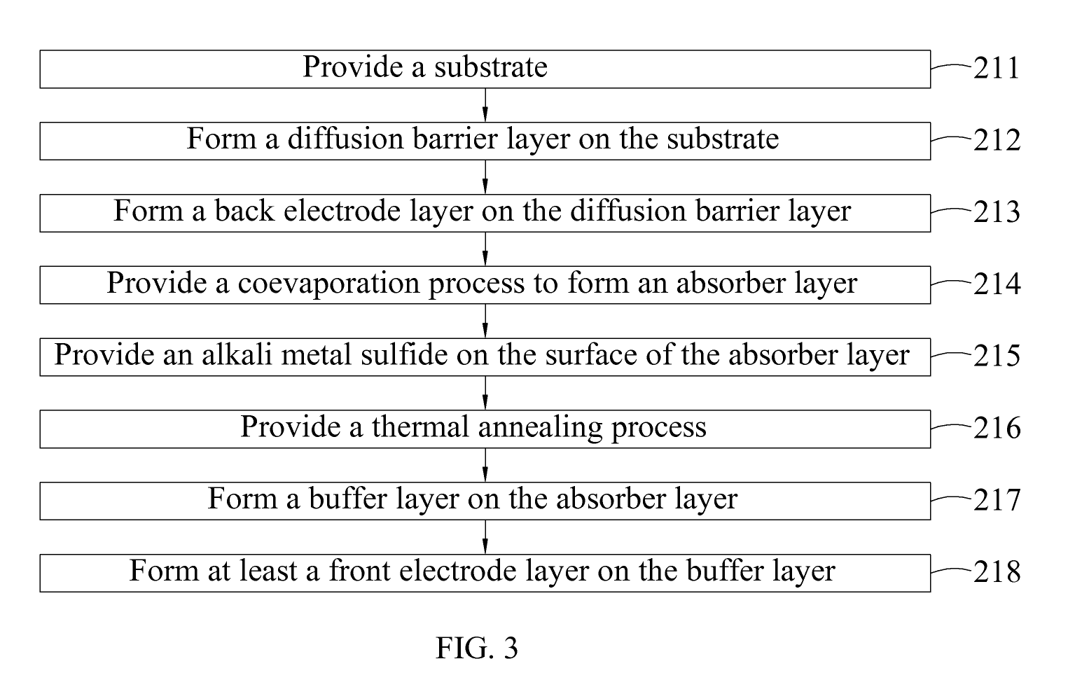

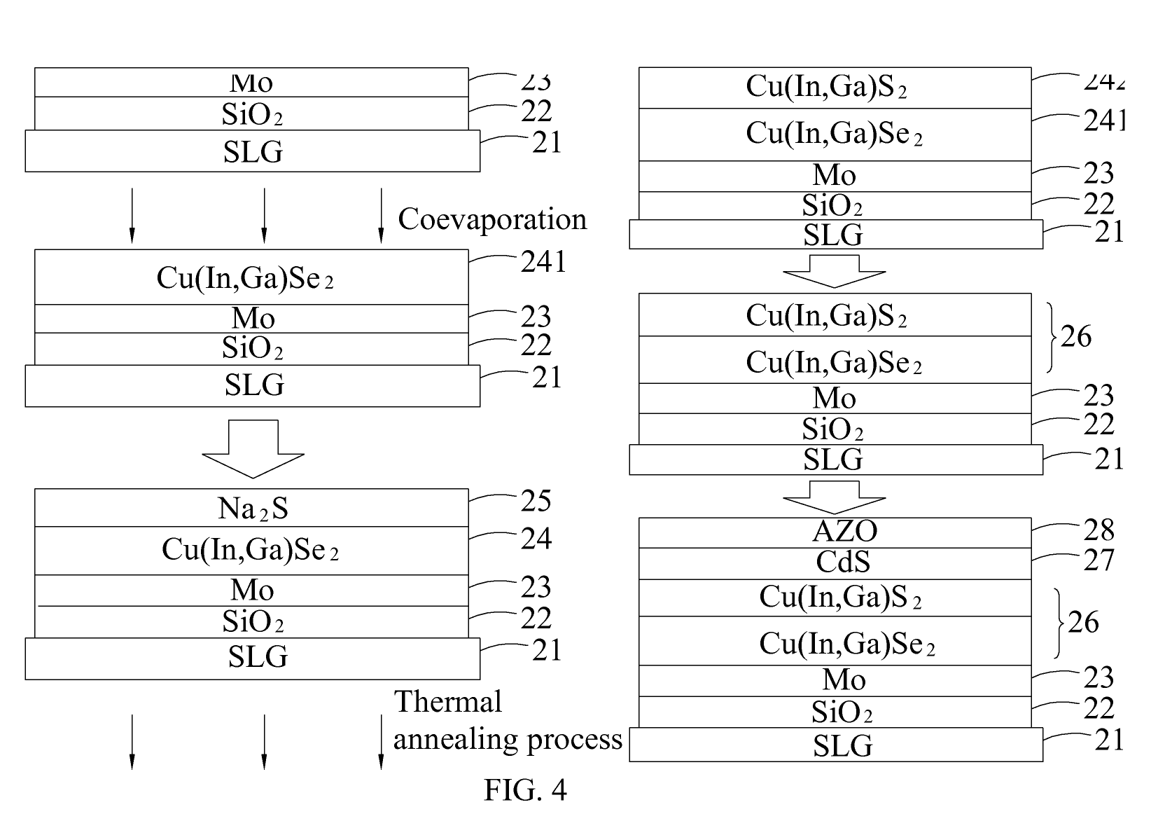

According to a second preferred embodiment of the present invention, there is provided another method of manufacturing a thin-film solar cell. Please refer to FIGS. 3 and 4. The method of manufacturing a thin-film solar cell according to the second preferred embodiment of the present invention includes the following steps:

Step 211: Providing a substrate 21. In the illustrated second preferred embodiment, the substrate is a soda-lime glass (SLG) substrate.

Step 212: Forming a diffusion barrier layer 22 on the substrate 21. In the illustrated second preferred embodiment, the diffusion barrier layer 22 is formed of SiO₂. The diffusion barrier layer is an optional layer in the thin film solar cell. Thus, the step 212 can be omitted if the thin film solar cell does not have such structure.

Step 213: Forming a back electrode layer 23 on the diffusion barrier layer 22. A material for forming the back electrode layer 23 can be Mo, Ag, Al, Cr, Ti, Ni or Au; or can be FTO, ITO, ZnO, AZO, GZO, BZO or IZO.

Step 214: Providing a coevaporation process, so that an absorber layer 24 having a chalcopyrite Cu(In, Ga)Se₂ structure 241 is formed on the back electrode layer 23.

Step 215: Providing an alkali metal sulfide 25 for depositing on an upper surface of the absorber layer 24. The alkali metal sulfide 25 can be Na₂S, Li₂S, K₂S, Rb₂S or Cs₂S. What is to be noted is the absorber layer 24 has a relatively high temperature due to the coevaporation process in the previous step 214. Particularly, in the event the absorber layer 24 remains at a high temperature during the step 215, a Cu(In, Ga)S₂ or Cu(In, Ga)(Se,S)₂ structure 242 would be naturally formed on the surface of the chalcopyrite Cu(In, Ga)Se₂ structure 241 of the absorber layer 24. In this case, a thermal annealing process in the following step 216 can be omitted. On the other hand, in the event the absorber layer 24 has a temperature lowered to a predetermined level during the step 215, the thermal annealing process in the following step 216 must be carried out. In the illustrated second preferred embodiment of the present invention, the alkali metal sulfide 25 is Na₂S.

Step 216: Providing a thermal annealing process to obtain a further increased process temperature, so that a Cu(In, Ga)S₂ or Cu(In, Ga)(Se,S)₂ structure 242 is further formed on the chalcopyrite Cu(In, Ga)Se₂ structure 241 of the absorber layer 24 to form an absorber layer 26.

Step 217: Forming at least a buffer layer 27 on the absorber layer 26. The buffer layer 27 can be formed of CdS, ZnS, In₂S₃, CdSe, ZnSe, In₂Se₃, TiO₂, SnO₂, ZnO, or ZnMgO. In the illustrated second preferred embodiment, the buffer layer is formed of CdS.

Step 218: Forming at least a front electrode layer 28 on the buffer layer 27. The front electrode layer 28 can be formed of FTO, ITO, ZnO, AZO, GZO, BZO, or IZO. In the illustrated second preferred embodiment, the front electrode layer is formed of AZO.

In a third preferred embodiment according to the present invention, there is provided a thin-film solar cell, which is manufactured using a method according to the first preferred embodiment of the present invention as shown in FIGS. 1, 2A and 2B.

In a fourth preferred embodiment according to the present invention, there is provided a thin-film solar cell, which is manufactured using a method according to the second preferred embodiment of the present invention as shown in FIGS. 3 and 4.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A method of manufacturing thin-film solar cell, comprising the following steps:
providing a substrate;
forming a back electrode layer on the substrate;
forming a precursor layer on the back electrode layer; and the precursor layer including at least Cu, In and Ga;
providing an alkali layer on the precursor layer;
providing a selenization process, so that the precursor layer is selenized and an absorber layer having a Cu(In, Ga)Se₂ structure is formed;
forming at least a buffer layer on the absorber layer; and
forming at least a front electrode layer on the buffer layer;
wherein an atomic percentage concentration of an alkali metal in the absorber layer is ranged between 0.01% and 10%; and the atomic percentage concentration of the alkali metal in the absorber layer closer to the back electrode layer is lower than the atomic percentage concentration of the alkali metal in the absorber layer closer to the buffer layer.

2. The method of manufacturing thin-film solar cell as claimed in claim 1, further comprising a step of forming a diffusion barrier layer on the substrate before the back electrode layer is formed.

3. The method of manufacturing thin-film solar cell as claimed in claim 1, wherein the selenization process enables Se to diffuse from an upper surface of the precursor layer into the precursor layer and the precursor layer further includes Se.

4. The method of manufacturing thin-film solar cell as claimed in claim 1, wherein the alkali layer is formed of an alkali metal selected from the group consisting of Li, Na, K, Rb, Cs and any chemical compound thereof, or formed of a sulfide, and the sulfide is selected from the group consisting of Li₂S, Na₂S, K₂S, Rb₂S, and Cs₂S.

5. The method of manufacturing thin-film solar cell as claimed in claim 1, wherein, in the selenization process, a Se source is used; and the Se source is selected from the group consisting of H₂Se, Se, Se vapor, and diethylselenide.

6. The method of manufacturing thin-film solar cell as claimed in claim 1, wherein the precursor layer further includes Ag and Al.

7. The method of manufacturing thin-film solar cell as claimed in claim 1, wherein the back electrode layer is formed of a material selected from the group consisting of Mo, Ag, Al, Cr, Ti, Ni and Au, or formed of a material selected from the group consisting of FTO, ITO, ZnO, AZO, GZO, BZO and IZO.

8. The method of manufacturing thin-film solar cell as claimed in claim 1, wherein the buffer layer is formed of a material selected from the group consisting of CdS, ZnS, In₂S₃, CdSe, ZnSe, In₂Se₃, TiO₂, SnO₂, ZnO, and ZnMgO.

9. The method of manufacturing thin-film solar cell as claimed in claim 1, wherein the front electrode layer is formed of a material selected from the group consisting of FTO, ITO, ZnO, AZO, GZO, BZO and IZO.

10. A thin-film solar cell, comprising:
a substrate;
a back electrode layer formed on the substrate;
an absorber layer having a Cu (In, Ga)Se₂ structure, disposed on the back electrode layer, and formed by a precursor layer and an alkali layer via a selenization process, and the back electrode layer including at least Cu, In and Ga;
at least a buffer layer formed on the absorber layer; and
at least a front electrode layer formed on the buffer layer;
wherein an atomic percentage concentration of an alkali metal in the absorber layer is ranged between 0.01% and 10%; and the atomic percentage concentration of the alkali metal in the absorber layer closer to the back electrode layer is lower than the atomic percentage concentration of the alkali metal in the absorber layer closer to the buffer layer.

11. The thin-film solar cell as claimed in claim 10, further comprising a diffusion barrier layer formed on the substrate before the back electrode layer is formed.

12. The thin-film solar cell as claimed in claim 10, wherein the selenization process enables Se to diffuse from an upper surface of the precursor layer into the precursor layer and the precursor layer further includes Se.

13. The thin-film solar cell as claimed in claim 10, wherein the alkali layer is formed of an alkali metal selected from the group consisting of Li, Na, K, Rb, Cs and any chemical compound thereof, or formed of a sulfide, and the sulfide is selected from the group consisting of Li₂S, Na₂S, K₂S, Rb₂S, and Cs₂S.

14. The thin-film solar cell as claimed in claim 10, wherein, in the selenization process, a Se source is used; and the Se source is selected from the group consisting of H₂Se, Se, Se vapor, and diethylselenide.

15. The thin-film solar cell as claimed in claim 10, wherein the precursor layer further includes Ag and Al.

16. The thin-film solar cell as claimed in claim 10, wherein the back electrode layer is formed of a material selected from the group consisting of Mo, Ag, Al, Cr, Ti, Ni and Au, or formed of a material selected from the group consisting of FTO, ITO, ZnO, AZO, GZO, BZO and IZO.

17. The thin-film solar cell as claimed in claim 10, wherein the buffer layer is formed of a material selected from the group consisting of CdS, ZnS, In₂S₃, CdSe, ZnSe, In₂Se₃, TiO₂, SnO₂, ZnO, and ZnMgO.

18. The thin-film solar cell as claimed in claim 10, wherein the front electrode layer is formed of a material selected from the group consisting of FTO, ITO, ZnO, AZO, GZO, BZO and IZO.

19. A method of manufacturing thin-film solar cell, comprising the following steps:
providing a substrate;
forming a back electrode layer on the substrate;
providing a coevaporation process, so that an absorber layer having a chalcopyrite Cu(In, Ga)Se₂ structure is formed on the back electrode layer;
providing an alkali metal sulfide for depositing on the absorber layer;
providing a heat treatment process, so that a Cu(In, Ga)S₂ or Cu(In, Ga)(Se,S)₂ structure is formed on a surface of the absorber layer;
forming at least a buffer layer on the absorber layer; and
forming at least a front electrode layer on the buffer layer.

20. The method of manufacturing thin-film solar cell as claimed in claim 19, further comprising a step of forming a diffusion barrier layer on the substrate before the back electrode layer is formed.

21. The method of manufacturing thin-film solar cell as claimed in claim 19, wherein the alkali metal sulfide is selected from the group consisting of Li₂S, Na₂S, K₂S, Rb₂S, and Cs₂S.

22. The method of manufacturing thin-film solar cell as claimed in claim 19, wherein the back electrode layer is formed of a material selected from the group consisting of Mo, Ag, Al, Cr, Ti, Ni and Au, or formed of a material selected from the group consisting of FTO, ITO, ZnO, AZO, GZO, BZO and IZO.

23. The method of manufacturing thin-film solar cell as claimed in claim 19, wherein the buffer layer is formed of a material selected from the group consisting of CdS, ZnS, In₂S₃, CdSe, ZnSe, In₂Se₃, TiO₂, SnO₂, ZnO, and ZnMgO.

24. The method of manufacturing thin-film solar cell as claimed in claim 19, wherein the front electrode layer is formed of a material selected from the group consisting of FTO, ITO, ZnO, AZO, GZO, BZO and IZO.

25. The method of manufacturing thin-film solar cell as claimed in claim 19, wherein an atomic percentage concentration of an alkali metal in the absorber layer is ranged between 0.01% and 10%; and the atomic percentage concentration of the alkali metal in the absorber layer closer to the back electrode layer is lower than the atomic percentage concentration of the alkali metal in the absorber layer closer to the buffer layer.
